(19) United States
(12) Patent Application Publication
(10) Pub. No.: US 2023/0268164 A1
(43) Pub. Date: Aug. 24, 2023

(54) SUBSTRATE PROCESSING APPARATUS

(71) Applicant: Tokyo Electron Limited, Tokyo (JP)

(72) Inventors: Hideki SUGIYAMA, Miyagi (JP); Shojiro YAHATA, Miyagi (JP); Shinya YAMANAKA, Miyagi (JP)

(73) Assignee: Tokyo Electron Limited, Tokyo (JP)

(21) Appl. No.: 18/113,862

(22) Filed: Feb. 24, 2023

(30) Foreign Application Priority Data
Feb. 24, 2022 (JP) 2022-027110

(51) Int. Cl. H01J 37/32

(52) U.S. Cl. CPC H01J 37/32449; C23C 16/45565

(57) ABSTRACT

There is provided a substrate processing apparatus including: a processing chamber; a substrate support that is disposed in the processing chamber and holds a substrate; and a shower head facing the substrate support, the shower head including a shower plate formed with a gas flow path through which a gas is discharged, and a cooling plate holding and cooling the shower plate, and the cooling plate including a first plate having a gas distribution layer through which the gas is distributed, a second plate having a coolant passage through which a coolant is supplied and a gas diffusion space into which the gas distributed by the gas distribution layer is supplied, and a fastening member fastening the first plate and the second plate.

### CROSS-REFERENCE TO RELATED APPLICATIONS

This application claims priority to Japanese Patent Application No. 2022-027110, filed on Feb. 24, 2022, the entire contents of which are incorporated herein by reference.

### TECHNICAL FIELD

The present disclosure relates to a substrate processing apparatus.

### BACKGROUND

Patent Document 1 discloses a gas distribution plate assembly that includes a base plate including a metal matrix composite and a perforated faceplate including a silicon disk coupled to the base plate by an adhesive layer.

Further, Patent Document 2 discloses a shower head assembly that includes an electrode plate and a ceramic substrate which supports the electrode plate to supply a gas, in which the ceramic substrate includes a first gas diffusion space formed on a center side of the substrate, a second gas diffusion space formed on a peripheral side of the substrate, a first heater electrode layer provided at a position above the first gas diffusion space, a second heater electrode layer provided at a position above the second gas diffusion space, a first coolant passage formed at a position above or below the first heater electrode layer which is a position above the first gas diffusion space, a second coolant passage formed at a position above or below the second heater electrode layer which is a position above the second gas diffusion space, a first gas supply path for supplying a gas via the first gas diffusion space, and a second gas supply path for supplying a gas via the second gas diffusion space, and the shower head assembly is manufactured such that there is no joining surface inside the substrate.

### PRIOR ART DOCUMENTS

### Patent Documents

Patent Document 1: JP 2019-523995A

Patent Document 2: JP 2015-95551A

### SUMMARY

In one aspect, the present disclosure provides a substrate processing apparatus that improves a freedom degree of design of a gas flow path.

In order to solve the above-described problem, according to one aspect, there is provided a substrate processing apparatus including: a processing chamber; a substrate support that is disposed in the processing chamber and holds a substrate; and a shower head facing the substrate support, the shower head including a shower plate formed with a gas flow path through which a gas is discharged, and a cooling plate holding and cooling the shower plate, and the cooling plate including a first plate having a gas distribution layer through which the gas is distributed, a second plate having a coolant passage through which a coolant is supplied and a gas diffusion space into which the gas distributed by the gas distribution layer is supplied, and a fastening member fastening the first plate and the second plate.

### BRIEF DESCRIPTION OF THE DRAWINGS

FIG. 1 is an example of a diagram illustrating a configuration example of a capacitively-coupled substrate processing apparatus.

FIG. 2 is an example of a cross-sectional view illustrating a configuration of a cooling plate according to the present embodiment.

FIG. 3 is an example of an exploded cross-sectional view of the cooling plate according to the present embodiment.

FIG. 4 is an example of a top view illustrating a configuration of a gas uniform distribution layer.

FIG. 5 is an example of a bottom view illustrating the configuration of the gas uniform distribution layer.

FIG. 6 is an example of a top view illustrating a configuration of a flow path forming layer.

FIG. 7 is an example of a bottom view illustrating the configuration of the flow path forming layer.

FIG. 8 is another example of the top view illustrating the configuration of the gas uniform distribution layer.

FIG. 9 is another example of the bottom view illustrating the configuration of the gas uniform distribution layer.

FIG. 10 is an example of a cross-sectional view illustrating a structure of a cooling plate according to a reference example.

FIGS. 11A and 11B are diagrams comparing the cooling plate according to the present embodiment and the cooling plate according to the reference example.

### DETAILED DESCRIPTION

Hereinafter, various exemplary embodiments will be described in detail with reference to the drawings. Further, like reference numerals will be given to like or corresponding parts throughout the drawings.

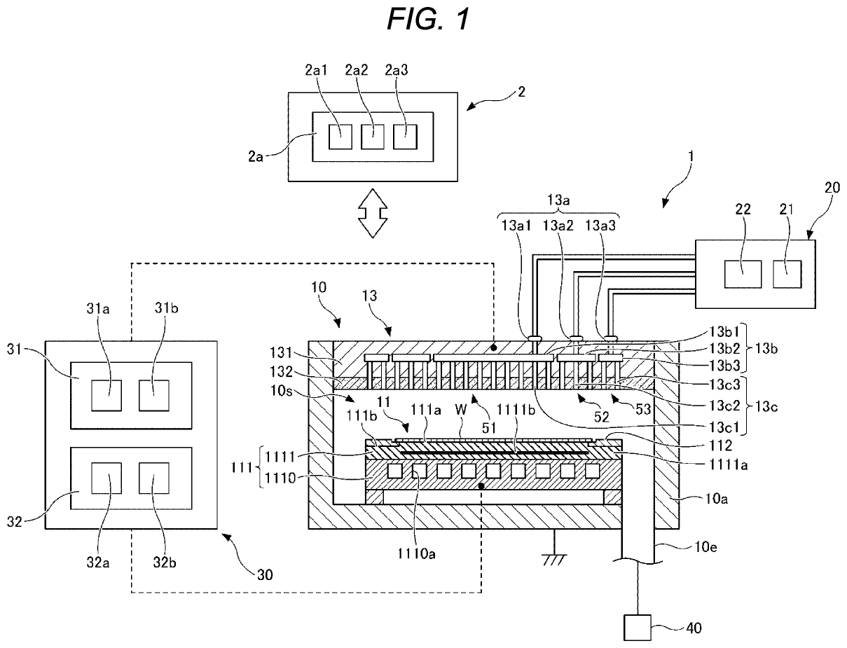

Hereinafter, an example of the configuration example of a plasma processing system will be described. FIG. 1 is an example of a diagram illustrating a configuration example of a capacitively-coupled substrate processing apparatus.

The plasma processing system includes a capacitively-coupled substrate processing apparatus 1 and a controller 2. The capacitively-coupled substrate processing apparatus 1 includes a plasma processing chamber (processing chamber) 10, a gas supply 20, a power source 30, and an exhaust system 40. Further, the substrate processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space 10s. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 and/or a direct current (DC) power source 32 to be described below may be disposed inside the ceramic member 1111a. In this case, at least one RF/DC electrode functions as the lower electrode. In a case where a bias RF signal and/or a DC signal to be described below are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 includes at least one gas supply port 13a (13a1 to 13a3), at least one gas diffusion chamber 13b (13b1 to 13b3), and a plurality of gas introduction ports 13c (13c1 to 13c3). The processing gas supplied to the gas supply port 13a passes through the gas diffusion chamber 13b and is introduced into the plasma processing space 10s from the plurality of gas introduction ports 13c.

Further, the shower head 13 illustrated in FIG. 1 includes a gas introduction portion 51, a gas introduction portion 52, and a gas introduction portion 53. The gas introduction portion 51 introduces a gas into a central region (center region) of the substrate W in the plasma processing chamber 10. The gas introduction portion 52 introduces a gas into a region (intermediate region) outside the gas introduction portion 51. The gas introduction portion 53 introduces a gas into a region (edge region) outside the gas introduction portion 52. The gas introduction portion 51, the gas introduction portion 52, and the gas introduction portion 53 are concentrically disposed.

The gas diffusion chamber 13b includes a gas diffusion chamber 13b1, a gas diffusion chamber 13b2, and a gas diffusion chamber 13b3.

The gas supply port 13a1 and the plurality of gas introduction ports 13c1 are connected to the gas diffusion chamber 13b1 to allow gases to flow therethrough. The gas introduction portion 51 includes the gas supply port 13a1, the gas diffusion chamber 13b1, and the plurality of gas introduction ports 13c1. Further, the gas supply port 13a2 and the plurality of gas introduction ports 13c2 are connected to the gas diffusion chamber 13b2 to allow gases to flow therethrough. The gas introduction portion 52 includes the gas supply port 13a2, the gas diffusion chamber 13b2, and the plurality of gas introduction ports 13c2. Further, the gas supply port 13a3 and the plurality of gas introduction ports 13c3 are connected to the gas diffusion chamber 13b3 to allow gases to flow therethrough. The gas introduction portion 53 includes the gas supply port 13a3, the gas diffusion chamber 13b3, and the plurality of gas introduction ports 13c3.

Further, the shower head 13 includes at least one upper electrode. The gas introduction unit may include, in addition to the shower head 13, one or a plurality of side gas injectors (SGI) that are attached to one or a plurality of openings formed in the sidewall 10a.

Further, the shower head 13 includes a cooling plate 131 and a shower plate 132. The cooling plate 131 is formed of, for example, aluminum and holds the shower plate 132. Further, the cooling plate 131 has a function of cooling the held shower plate 132. Further, the gas diffusion chamber 13b is formed in the cooling plate 131. The shower plate 132 is formed of, for example, Si, SiC, or the like, and includes the gas introduction port 13c.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Accordingly, a plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. In addition, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first bias DC signal is applied to at least one lower electrode. In one embodiment, the second DC generator 32b is configured to be connected to at least one upper electrode to generate a second DC signal. The generated second DC signal is applied to at least one upper electrode.

In various embodiments, at least one of the first and second DC signals may be pulsed. In this case, a sequence of voltage pulses is applied to at least one lower electrode and/or at least one upper electrode. The voltage pulse may have a pulse waveform of a rectangle, a trapezoid, a triangle, or a combination thereof. In one embodiment, a waveform generator for generating a sequence of voltage pulses from the DC signal is connected between the first DC generator 32a and at least one lower electrode. Accordingly, a voltage pulse generator is configured with the first DC generator 32a and the waveform generator. In a case where the voltage pulse generator is configured with the second DC generator 32b and the waveform generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The controller 2 processes computer-executable instructions for instructing the substrate processing apparatus 1 to execute various steps described in the present disclosure. The controller 2 may be configured to control each element of the substrate processing apparatus 1 to execute the various steps described herein below. In an embodiment, part or all of the controller 2 may be included in the substrate processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the substrate processing apparatus 1 via a communication line such as a local area network (LAN).

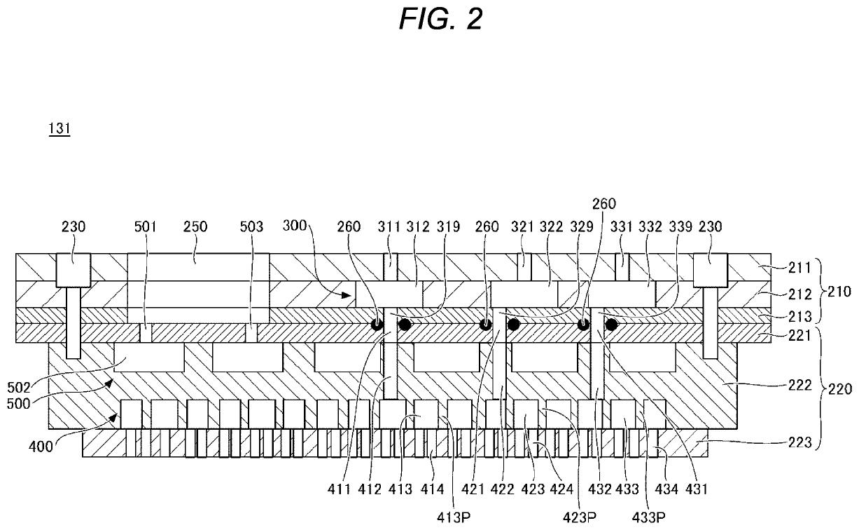

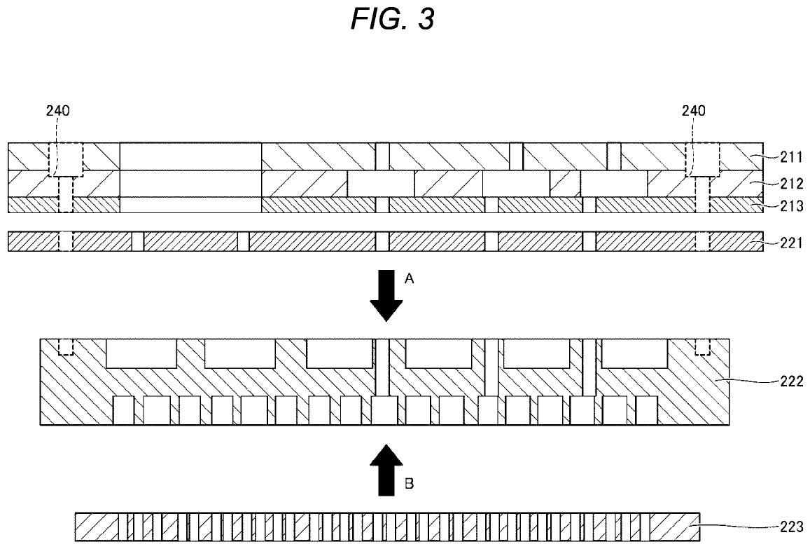

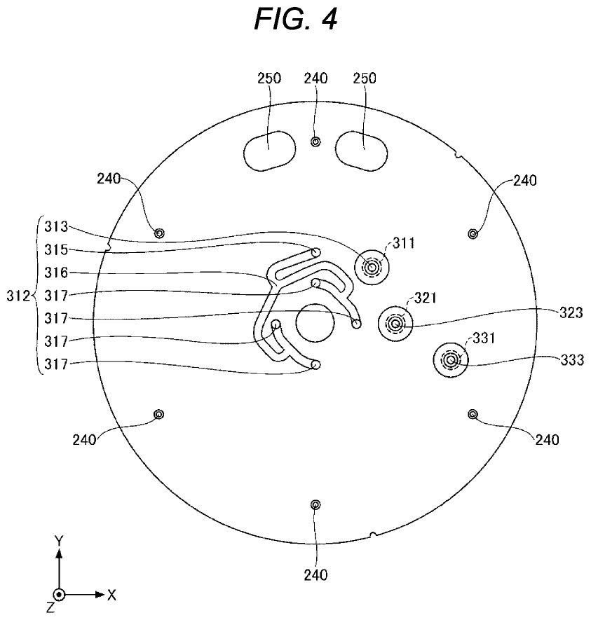

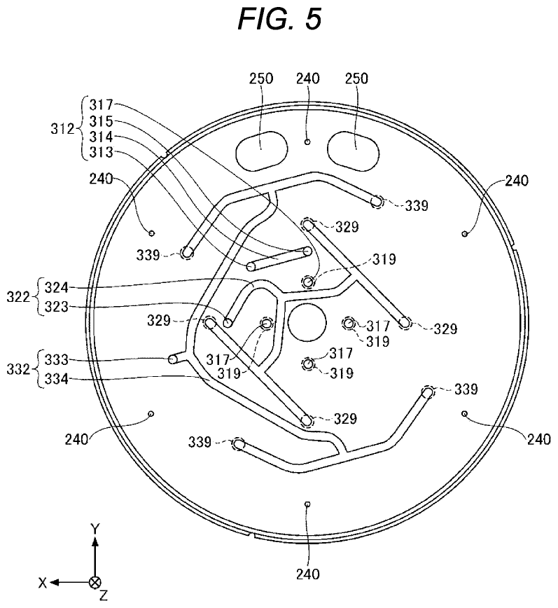

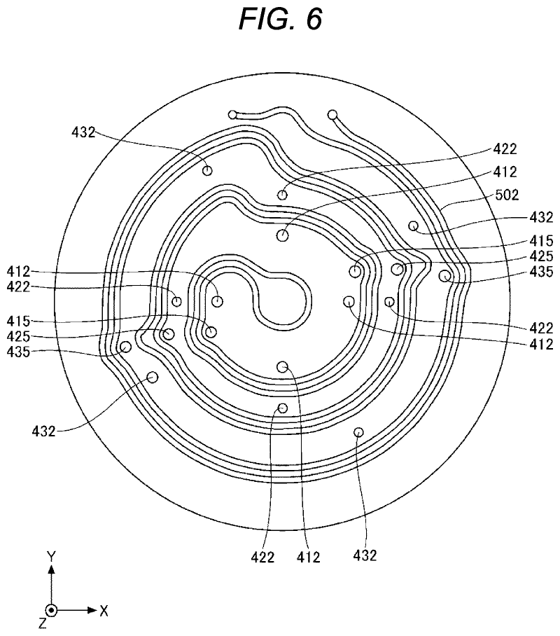

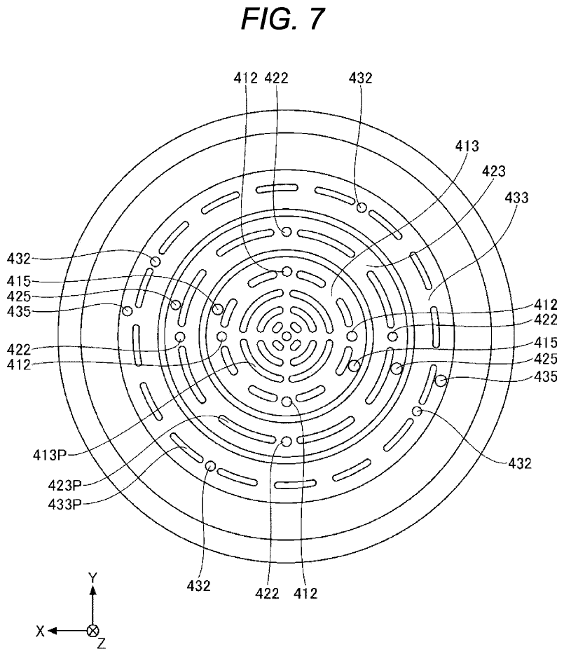

Next, the cooling plate 131 of the present embodiment will be further described with reference to FIGS. 2 to 7. FIG. 2 is an example of a cross-sectional view illustrating a configuration of the cooling plate 131 according to the present embodiment. FIG. 3 is an example of an exploded cross-sectional view of the cooling plate 131 according to the present embodiment. FIG. 4 is an example of a top view illustrating a configuration of a gas uniform distribution layer (gas distribution layer) 212. FIG. 5 is an example of a bottom view illustrating the configuration of the gas uniform distribution layer 212. In FIG. 4, positions corresponding to gas flow paths 311, 321, and 331 are illustrated by broken lines, and positions corresponding to gas flow paths 319, 329, and 339 are illustrated by broken lines in FIG. 5. FIG. 6 is an example of a top view illustrating a configuration of a flow path forming layer 222 as viewed in a direction A (see FIG. 3). FIG. 7 is an example of a bottom view illustrating the configuration of the flow path forming layer 222 as viewed in a B direction (see FIG. 3). In FIGS. 4 to 7, horizontal directions orthogonal to each other are respectively referred to as an X-direction and a Y-direction and a height direction is referred to as a Z-direction.

The cooling plate 131 has a first plate 210 in which a gas distribution flow path 300 is formed, and a second plate 220 in which a gas diffusion flow path 400 and a coolant passage 500 are formed. The first plate 210 and the second plate 220 are joined to each other by bolts 230.

The first plate 210 has a connection interface (IF) layer 211, the gas uniform distribution layer 212, and a first intermediate interface (IF) layer 213. The first plate 210 is formed with diffusion joining, brazing, or the like the plate-shaped connection IF layer 211, the gas uniform distribution layer 212, and the first intermediate IF layer 213. Further, the first plate 210 is formed of, for example, aluminum, stainless steel (SUS), or the like.

A gas is supplied from the gas supply 20 to the connection IF layer 211. That is, the connection IF layer 211 has the gas flow path 311 connected to the gas supply port 13a1 (see FIG. 1). Further, the connection IF layer 211 has the gas flow path 321 connected to the gas supply port 13a2 (see FIG. 1). Further, the connection IF layer 211 has the gas flow path 331 connected to the gas supply port 13a3 (see FIG. 1). The gas flow paths 311, 321, and 331 are flow paths passing through the connection IF layer 211 in a plate thickness direction.

The gas uniform distribution layer 212 distributes the gas supplied from the connection IF layer 211. That is, the gas uniform distribution layer 212 has a distribution flow path 312 that distributes a gas supplied from the gas flow path 311 provided in the connection IF layer 211 to a plurality of gas flow paths 319 provided in the first intermediate IF layer 213. The distribution flow path 312 has a through-flow path 313, a communication flow path 314, a through-flow path 315, a distribution flow path 316, and a through-flow path 317 (see FIGS. 4 and 5). The through-flow path 313 is a flow path passing through the gas uniform distribution layer 212 in the plate thickness direction, and communicates the gas flow path 311 and the communication flow path 314 of the connection IF layer 211. The communication flow path 314 is a flow path formed with a recessed groove formed on a lower surface side of the gas uniform distribution layer 212 and an upper surface of the first intermediate IF layer 213, and communicates the through-flow path 313 and the through-flow path 315. The through-flow path 315 is a flow path passing through the gas uniform distribution layer 212 in the plate thickness direction, and communicates the communication flow path 314 and the distribution flow path 316. The distribution flow path 316 is a flow path formed with a recessed groove formed on an upper surface side of the gas uniform distribution layer 212 and a lower surface of the connection IF layer 211, and communicates the through-flow path 315 and the through-flow path 317. Further, the distribution flow path 316 branches into a plurality (four in the examples illustrated in FIGS. 4 and 5) from the through-flow path 315 toward a plurality of through-flow paths 317. Further, the distribution flow path 316 is formed such that flow path lengths from the through-flow path 315 to the respective through-flow paths 317 are equal to each other. The through-flow path 317 is a flow path passing through the gas uniform distribution layer 212 in the plate thickness direction, and communicates the distribution flow path 316 and the gas flow path 319 of the first intermediate IF layer 213.

Further, the gas uniform distribution layer 212 has a distribution flow path 322 that distributes a gas supplied from the gas flow path 321 provided in the connection IF layer 211 to a plurality of gas flow paths 329 provided in the first intermediate IF layer 213 (see FIGS. 4 and 5). The distribution flow path 322 has a through-flow path 323 and a distribution flow path 324. The through-flow path 323 is a flow path passing through the gas uniform distribution layer 212 in the plate thickness direction, and communicates the gas flow path 321 and the distribution flow path 324 of the connection IF layer 211. The distribution flow path 324 is a flow path formed with a recessed groove formed on the lower surface side of the gas uniform distribution layer 212 and the upper surface of the first intermediate IF layer 213, and communicates the through-flow path 323 and the gas flow path 329 of the first intermediate IF layer 213. Further, the distribution flow path 324 branches into a plurality (four in the examples illustrated in FIGS. 4 and 5) from the through-flow path 323 toward the plurality of gas flow paths 329. Further, the distribution flow path 324 is formed such that flow path lengths from the through-flow path 323 to the respective gas flow paths 329 are equal to each other.

Further, the gas uniform distribution layer 212 has a distribution flow path 332 that distributes a gas supplied from the gas flow path 331 provided in the connection IF layer 211 to a plurality of gas flow paths 339 provided in the first intermediate IF layer 213 (see FIGS. 4 and 5). The distribution flow path 332 has a through-flow path 333 and a distribution flow path 334. The through-flow path 333 is a flow path passing through the gas uniform distribution layer 212 in the plate thickness direction, and communicates the gas flow path 331 and the distribution flow path 334 of the connection IF layer 211. The distribution flow path 334 is a flow path formed with a recessed groove formed on the lower surface side of the gas uniform distribution layer 212 and the upper surface of the first intermediate IF layer 213, and communicates the through-flow path 333 and the gas flow path 339 of the first intermediate IF layer 213. Further, the distribution flow path 334 branches into a plurality (4 in the examples illustrated in FIGS. 4 and 5) from the through-flow path 333 toward the plurality of gas flow paths 339. Further, the distribution flow path 334 is formed such that flow path lengths from the through-flow path 333 to the respective gas flow paths 339 are equal to each other.

In this manner, the gas uniform distribution layer 212 in which the distribution flow paths 312, 322, and 332 for distributing the gas supplied from the gas flow paths 311, 321, and 331 provided in the connection IF layer 211 to the plurality of gas flow paths 319, 329, and 339 provided in the first intermediate IF layer 213 are formed has in a multilayer structure. That is, as illustrated in FIGS. 4 and 5, the gas uniform distribution layer 212 has a two-layer structure having an upper surface gas flow path formed on the upper surface side of the gas uniform distribution layer 212, a lower surface gas flow path formed on the lower surface side of the gas uniform distribution layer 212, and a through-gas flow path passing through the upper surface side (upper surface gas flow path) and the lower surface side (lower surface gas flow path) of the gas uniform distribution layer 212. In the examples illustrated in FIGS. 4 and 5, the distribution flow path 312 has the distribution flow path 316 serving as the upper surface gas flow path, the communication flow path 314 serving as the lower surface gas flow path, and the through-flow paths 313, 315, and 317 serving as the through-gas flow paths. The distribution flow path 322 has the distribution flow path 324 serving as the lower surface gas flow path and the through-flow path 323 serving as the through-gas flow path. The distribution flow path 332 has the distribution flow path 334 serving as the lower surface gas flow path and the through-flow path 333 serving as the through-gas flow path. The multilayer structure is not limited to two layers, and may have two or more layers.

The first intermediate IF layer 213 supplies the gas distributed in the gas uniform distribution layer 212 to a second intermediate interface (IF) layer 221 of the second plate 220. That is, the first intermediate IF layer 213 has the four gas flow paths 319, the four gas flow paths 329, and the four gas flow paths 339. The gas flow paths 319, 329, and 339 are flow paths passing through the first intermediate IF layer 213 in the plate thickness direction.

Further, the first plate 210 has counterbored holes 240 through which the bolts 230 are inserted when the first plate 210 and the second plate 220 are fixed to each other by the bolts 230.

Further, the first plate 210 has through-holes 250 through which a coolant pipe (not illustrated) connected to the second intermediate IF layer 221 of the second plate 220 is inserted.

The second plate 220 includes the second intermediate IF layer 221, the flow path forming layer 222, and a gas hole layer 223. The second plate 220 is formed with diffusion joining, brazing, or the like the plate-shaped second intermediate IF layer 221, the flow path forming layer 222, and the gas hole layer 223. Further, the second plate 220 is formed of, for example, aluminum, and after being joined by diffusion joining or the like, an alumite process is executed on a surface of the second plate 220, and thus the second plate 220 has plasma resistance. The second plate 220 is disposed closer to the plasma processing space 10s than the first plate 210.

The gas is supplied from the first intermediate IF layer 213 of the first plate 210 to the second intermediate IF layer 221. That is, the second intermediate IF layer 221 has a gas flow path 411 that communicates with the gas flow path 319. Further, the second intermediate IF layer 221 has a gas flow path 421 that communicates with the gas flow path 329. Further, the second intermediate IF layer 221 has a gas flow path 431 that communicates with the gas flow path 339. The gas flow paths 411, 421, and 431 are flow paths passing through the second intermediate IF layer 221 in the plate thickness direction. Further, sealing members 260 are provided on a facing surface of the first plate 210 and the second plate 220.

The sealing member 260 seals the gas flow path 319 and the gas flow path 411 while communicating the gas flow path 319 and the gas flow path 411. Further, the sealing member 260 seals the gas flow path 329 and the gas flow path 421 while communicating the gas flow path 329 and the gas flow path 421. Further, the sealing member 260 seals the gas flow path 339 and the gas flow path 431 while communicating the gas flow path 339 and the gas flow path 431.

Further, the second intermediate IF layer 221 has coolant passages 501 and 503. The coolant passages 501 and 503 are flow paths passing through the second intermediate IF layer 221 in the plate thickness direction.

Further, the second intermediate IF layer 221 has through-holes (not illustrated) that communicate with liquid drain holes 415, 425, and 435 (see FIGS. 6 and 7) of the flow path forming layer 222 to be described below.

The flow path forming layer 222 has a gas diffusion space 413 through which the gas is supplied from the second intermediate IF layer 221. That is, the flow path forming layer 222 has a through-flow path 412 that communicates with the gas flow path 411, and the gas diffusion space 413. The through-flow path 412 is a flow path passing through the flow path forming layer 222 in the plate thickness direction, and communicates the gas flow path 411 of the second intermediate IF layer 221 and the gas diffusion space 413. The gas diffusion space 413 is a space having a circular shape formed with a recessed groove formed on a lower surface side of the flow path forming layer 222 and an upper surface of the gas hole layer 223, and corresponds to the gas diffusion chamber 13b1 illustrated in FIG. 1. A plurality of support columns 413P are provided in the gas diffusion space 413. Further, a plurality of (four in the example of FIG. 7) through-flow paths 412 are arranged at equal intervals on a circumference coaxial with a central axis of the gas diffusion space 413.

Further, the flow path forming layer 222 has the liquid drain hole (alumite film formation through-hole) 415 which is used for inserting an electrode (not illustrated) therethrough when an alumite process is performed on an inner wall surface (the gas flow path 411, the through-flow path 412, the gas diffusion space 413, and a gas hole 414) of the second plate 220 and used for exhausting a solution after the alumite process. The liquid drain hole 415 is a flow path passing through the flow path forming layer 222 in the plate thickness direction, and communicates the through-hole (not illustrated) of the second intermediate IF layer 221 and the gas diffusion space 413. The liquid drain hole 415 is sealed by a plug (filling plug).

In the same manner, the flow path forming layer 222 has a through-flow path 422 which communicates with the gas flow path 421, a gas diffusion space 423, and the liquid drain hole (alumite film formation through-hole) 425. The gas diffusion space 423 is a space having an annular shape formed with a recessed groove formed on the lower surface side of the flow path forming layer 222 and the upper surface of the gas hole layer 223, and corresponds to the gas diffusion chamber 13b2 illustrated in FIG. 1. A plurality of support columns 423P are provided in the gas diffusion space 423. Further, a plurality of (four in the example of FIG. 7) through-flow paths 422 are arranged at equal intervals on a circumference coaxial with a central axis of the gas diffusion space 423. Further, the liquid drain hole 425 is sealed by a plug (filling plug).

Further, the flow path forming layer 222 has a through-flow path 432 that communicates with the gas flow path 431, a gas diffusion space 433, and the liquid drain hole (alumite film formation through-hole) 435. The gas diffusion space 433 is a space having an annular shape formed with a recessed groove formed on the lower surface side of the flow path forming layer 222 and the upper surface of the gas hole layer 223, and corresponds to the gas diffusion chamber 13b3 illustrated in FIG. 1. A plurality of support columns 433P are provided in the gas diffusion space 433. Further, a plurality of (four in the example of FIG. 7) through-flow paths 432 are arranged at equal intervals on a circumference coaxial with a central axis of the gas diffusion space 433. Further, the liquid drain hole 435 is sealed by a plug (filling plug).

The gas hole layer 223 supplies the gas from the gas diffusion space 413 to the shower plate 132. That is, the gas hole layer 223 has a plurality of gas holes 414, 424, and 434. The gas hole 414 is a flow path passing through the gas hole layer 223 in the plate thickness direction, and communicates the gas diffusion space 413 and the plasma processing space 10s (see FIG. 1). The gas hole 424 is a flow path passing through the gas hole layer 223 in the plate thickness direction, and communicates the gas diffusion space 423 and the plasma processing space 10s. The gas hole 434 is a flow path passing through the gas hole layer 223 in the plate thickness direction, and communicates the gas diffusion space and the plasma processing space 10s.

As described above, a processing gas supplied from the gas supply port 13a1 is supplied to the gas diffusion space 413 via the gas flow path 311, the distribution flow path 312 (the through-flow path 313, the communication flow path 314, the through-flow path 315, the distribution flow path 316, and the through-flow path 317), the gas flow path 319, the gas flow path 411, and the through-flow path 412. The gas is supplied from the gas diffusion space 413 into the plasma processing space 10s via the gas hole 414 and the gas introduction port 13c1 (see FIG. 1) of the cooling plate 131. Further, a processing gas supplied from the gas supply port 13a2 is supplied into the gas diffusion space 423 via the gas flow path 321, the distribution flow path 322 (the through-flow path 323, and the distribution flow path 324), the gas flow path 329, the gas flow path 421, and the through-flow path 422. The gas is supplied from the gas diffusion space 423 into the plasma processing space 10s via the gas hole 424 and the gas introduction port 13c2 (see FIG. 1) of the cooling plate 131. Further, a processing gas supplied from the gas supply port 13a3 is supplied into the gas diffusion space 433 via the gas flow path 331, the distribution flow path 332 (the through-flow path 333, and the distribution flow path 334), the gas flow path 339, the gas flow path 431, and the through-flow path 432. The gas is supplied from the gas diffusion space 433 into the plasma processing space 10s via the gas hole 434 and the gas introduction port 13c3 (see FIG. 1) of the cooling plate 131.

Further, the flow path forming layer 222 has a coolant passage 502 that communicates with the coolant passages 501 and 503. The coolant passage 502 is a flow path formed with a recessed groove formed on an upper surface side of the flow path forming layer 222 and a lower surface of the second intermediate IF layer 221. A coolant supplied from the coolant passage 501 flows through the coolant passage 502, and is exhausted from the coolant passage 503. Here, heat from the plasma generated in the plasma processing space 10s enters the shower plate 132 (see FIG. 1). The cooling plate 131 can exhaust the heat, and cool the shower plate 132 by supplying the coolant to the coolant passage 502 of the second plate 220 in contact with the shower plate 132.

As described above, with the cooling plate 131 of the present embodiment, the gas uniform distribution layer 212 that uniformly distributes the gas supplied from the gas supply port 13a and supplies the gas to the gas diffusion chamber 13b can be separately provided. Accordingly, a structure of the cooling plate 131 can be simplified, and a manufacturing cost can be reduced. Further, SUS or the like can be used for the first plate 210, so that a selectivity of the material is improved. In addition, a freedom degree of flow path design can be improved.

Further, the distribution flow paths 312, 322, and 332 that branch into a tournament shape can have a multilayer structure. Accordingly, it is possible to shorten a flow path length, as compared with a case where the gas flow path makes a detour in one plane shape. Accordingly, in the substrate processing apparatus in which the gas is configured with pulses, a responsiveness of ON/OFF of the gas can be improved.

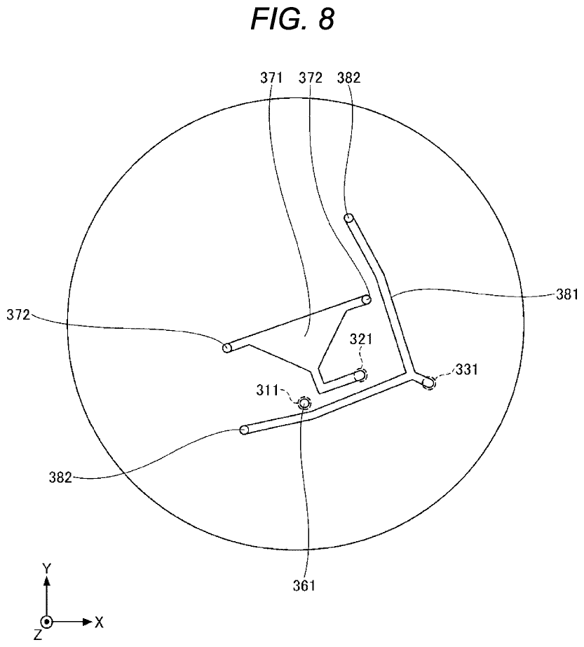

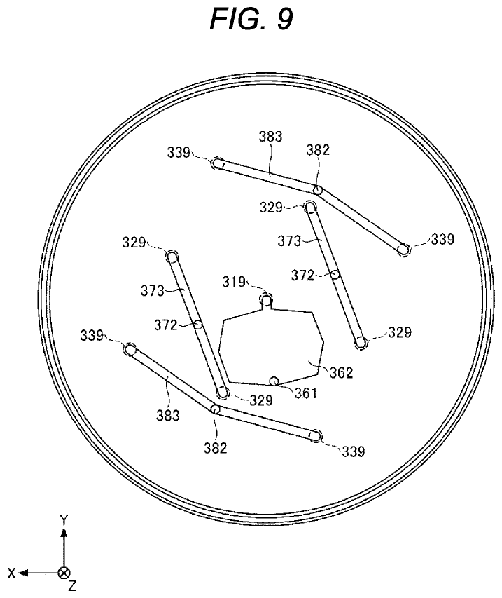

The shape of the gas uniform distribution layer 212 is not limited to the structures illustrated in FIGS. 4 and 5. FIG. 8 is another example of the top view illustrating the configuration of the gas uniform distribution layer 212. FIG. 9 is another example of the bottom view illustrating the configuration of the gas uniform distribution layer 212. In FIG. 8, positions corresponding to the gas flow paths 311, 321, and 331 are illustrated by broken lines, and the positions corresponding to the gas flow paths 319, 329, and are illustrated by broken lines in FIG. 9. In FIGS. 8 and 9, the horizontal directions orthogonal to each other are respectively referred to as the X direction and the Y-direction, and the height direction is referred to as the Z-direction.

The gas uniform distribution layer 212 illustrated in FIGS. 8 and 9 has a distribution flow path that distributes a gas supplied from the gas flow path 311 provided in the connection IF layer 211 to the plurality of gas flow paths 319 provided in the first intermediate IF layer 213. The distribution flow path has a through-flow path 361 and a communication flow path 362. The through-flow path 361 is a flow path passing through the gas uniform distribution layer 212 in the plate thickness direction, and communicates the gas flow path 311 and the communication flow path 362 of the connection IF layer 211. The communication flow path 362 is a flow path formed with a recessed groove formed on the lower surface side of the gas uniform distribution layer 212 and the upper surface of the first intermediate IF layer 213, and communicates the through-flow path 361 and the gas flow path 319 of the first intermediate IF layer 213.

Further, the gas uniform distribution layer 212 has a distribution flow path that distributes a gas supplied from the gas flow path 321 provided in the connection IF layer 211 to the plurality of gas flow paths 329 provided in the first intermediate IF layer 213. The distribution flow path has a distribution flow path 371 and a through-flow path 372. The distribution flow path 371 is a flow path formed with a recessed groove formed on the upper surface side of the gas uniform distribution layer 212 and the lower surface of the connection IF layer 211, and communicates the gas flow path 321 of the connection IF layer 211 and the through-flow path 372. The through-flow path 372 is a flow path passing through the gas uniform distribution layer 212 in the plate thickness direction, and communicates the distribution flow path 371 and a distribution flow path 373. The distribution flow path 373 is a flow path formed with a recessed groove formed on the lower surface side of the gas uniform distribution layer 212 and the upper surface of the first intermediate IF layer 213, and communicates the through-flow path 372 and the gas flow path 329 of the first intermediate IF layer 213.

Further, the gas uniform distribution layer 212 has a distribution flow path that distributes a gas supplied from the gas flow path 331 provided in the connection IF layer 211 to the plurality of gas flow paths 339 provided in the first intermediate IF layer 213. The distribution flow path has a distribution flow path 381 and a through-flow path 382. The distribution flow path 381 is a flow path formed with a recessed groove formed on the upper surface side of the gas uniform distribution layer 212 and the lower surface of the connection IF layer 211, and communicates the gas flow path 331 of the connection IF layer 211 and the through-flow path 382. The through-flow path 382 is a flow path passing through the gas uniform distribution layer 212 in the plate thickness direction, and communicates the distribution flow path 381 and a distribution flow path 383. The distribution flow path 383 is a flow path formed with a recessed groove formed on the lower surface side of the gas uniform distribution layer 212 and the upper surface of the first intermediate IF layer 213, and communicates the through-flow path 382 and the gas flow path 339 of the first intermediate IF layer 213.

That is, as illustrated in FIGS. 8 and 9, the gas uniform distribution layer 212 has a two-layer structure having an upper surface gas flow path formed on the upper surface side of the gas uniform distribution layer 212, a lower surface gas flow path formed on the lower surface side of the gas uniform distribution layer 212, and a through-gas flow path passing through the upper surface side (upper surface gas flow path) and the lower surface side (lower surface gas flow path) of the gas uniform distribution layer 212. In the examples illustrated in FIGS. 8 and 9, the flow path through which the gas from the gas flow path 311 is supplied to the gas flow path 319 has the communication flow path 362 serving as the lower surface gas flow path, and the through-flow path 361 serving as the through-gas flow path. Further, the distribution flow path through which the gas is distributed from the gas flow path 321 to the gas flow path 329 has the distribution flow path 371 serving as the upper surface gas flow path, the distribution flow path 373 serving as the lower surface gas flow path, and the through-flow path 372 serving as the through-gas flow path. Further, the distribution flow path through which the gas is distributed from the gas flow path 331 to the gas flow path 339 has the distribution flow path 381 serving as the upper surface gas flow path, the distribution flow path 383 serving as the lower surface gas flow path, and the through-flow path 382 serving as the through-gas flow path.

In this manner, in the gas uniform distribution layer 212 illustrated in FIGS. 8 and 9, flow path lengths can be made equal to each other, for three systems of gas. Further, volumes of the flow paths can be made equal to each other. Accordingly, it is possible to further improve the responsiveness when the gas supply is pulse-controlled.

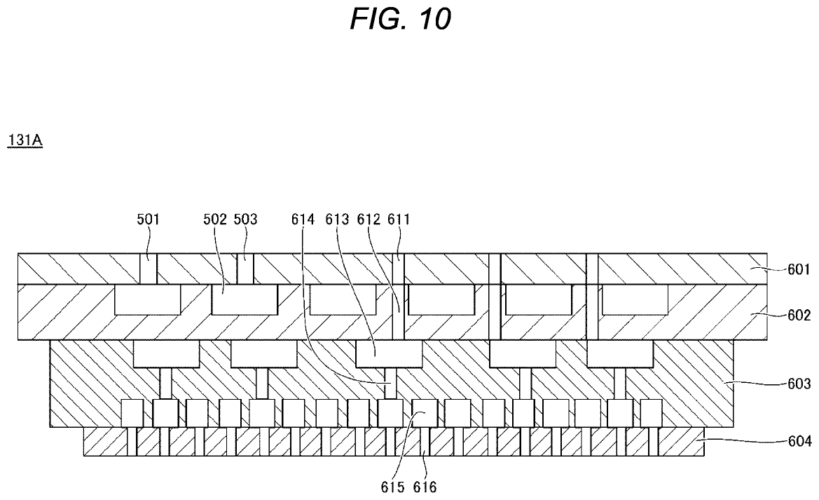

Next, a structure of a cooling plate 131A according to a reference example will be described with reference to FIG. 10. The cooling plate 131A according to the reference example includes a connection interface (IF) layer 601, a coolant passage forming layer 602, a gas distribution and diffusion layer 603, and a gas hole layer 604.

A gas flow path 611 is a flow path passing through the connection IF layer 601. A gas flow path 612 is a flow path that communicates with the gas flow path 611, and passes through the coolant passage forming layer 602. A distribution flow path 613 is a flow path formed with a recessed groove formed on an upper surface of the gas distribution and diffusion layer 603 and a lower surface of the coolant passage forming layer 602, and branches into a plurality of flow paths. A gas flow path 614 is a flow path that communicates with the distribution flow path 613, and passes through the gas distribution and diffusion layer 603. A gas diffusion space 615 is a space formed with a recessed groove formed on a lower surface of the gas distribution and diffusion layer 603 and an upper surface of the gas hole layer 604. A gas hole 616 is a flow path that communicates with the gas diffusion space 615, and passes through the gas hole layer 604. Accordingly, the gas supplied from the gas supply port 13a (see FIG. 1) is supplied to the distribution flow path 613 through the gas flow paths 611 and 612, distributed to a plurality of gas flow paths 614 by the distribution flow path 613, and supplied into the gas diffusion space 615. The gas is supplied from the gas diffusion space 615 to the gas hole 616.

The coolant passages 501 and 503 are flow paths passing through the connection IF layer 601. The coolant passage 502 is a flow path formed with a recessed groove formed in an upper surface of the coolant passage forming layer 602 and a lower surface of the connection IF layer 601. Accordingly, the coolant supplied from the coolant passage 501 flows through the coolant passage 502, and is exhausted from the coolant passage 503.

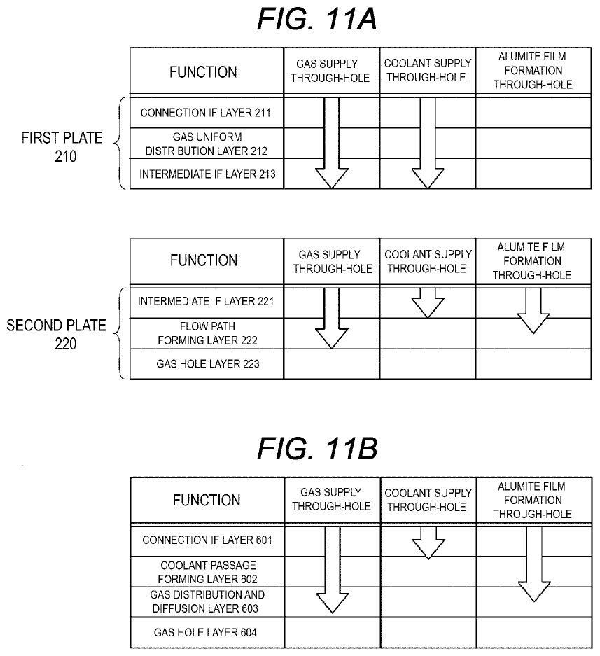

FIGS. 11A and 11B are graphs comparing the cooling plate 131 according to the present embodiment and the cooling plate 131A according to the reference example.

As illustrated in FIG. 11B, in the cooling plate 131A according to the reference example, a through-hole through which a gas is supplied is formed across the connection IF layer 601, the coolant passage forming layer 602, and the gas distribution and diffusion layer 603. Further, in the cooling plate 131A according to the reference example, a through-hole through which a coolant is supplied is formed across the connection IF layer 601. In addition, in the cooling plate 131A according to the reference example, an alumite film formation through-hole which is used for inserting an electrode rod therethrough when an alumite process is performed on an inner surface of the gas diffusion space 615 or the like and used for exhausting a solution after the alumite process is formed across the connection IF layer 601, the coolant passage forming layer 602, and the gas distribution and diffusion layer 603.

Here, the gas flow path 611 and the gas flow path 612 are coaxially formed. Meanwhile, the gas flow path 614 connected via the distribution flow path 613 is provided at a position axially different from the gas flow path 611 and the gas flow path 612. Therefore, on an upper surface side of the cooling plate 131A, the alumite film formation through-hole passing through from the upper surface side of the cooling plate 131A toward the gas diffusion space 615 is provided at a position different from the gas flow path 611. Therefore, the many alumite film formation through-holes pass through the upper surface of the coolant passage forming layer 602 forming a recessed groove to be the coolant passage 502 and the upper surface of the gas distribution and diffusion layer 603 forming a recessed groove to be the distribution flow path 613, and a freedom degree of design of the coolant passage 502 and the distribution flow path 613 is reduced.

In contrast, as illustrated in FIG. 11A, the gas uniform distribution layer 212 that uniformly distributes the gas is formed separately from the flow path forming layer 222 in which the coolant passage 502 and the gas diffusion spaces 413, 423, and 433 are formed. Therefore, the alumite film formation through-hole which is used for inserting an electrode rod therethrough when an alumite process is performed on inner surfaces of the gas diffusion spaces 413, 423, 433 and the like and used for exhausting a solution after the alumite process is formed across the second intermediate IF layer 221 and the flow path forming layer 222.

Therefore, the gas distribution flow path 300 can be laid out regardless of a position of the alumite film formation through-hole, and a freedom degree of design of the gas distribution flow path 300 can be improved. Further, a structure of the gas flow path can be formed in a simple manner, and a flow path length of the gas can be shortened. Accordingly, in the substrate processing apparatus in which the gas is configured with pulses, a responsiveness of ON/OFF of the gas can be improved.

Further, the gas flow path 411 and the through-flow path 412 are coaxially formed, and communicate with each other up to the gas diffusion space 413. In the same manner, the gas flow path 421 and the through-flow path 422 are coaxially formed, and communicate with each other up to the gas diffusion space 423. Further, the gas flow path 431 and the through-flow path 432 are coaxially formed, and communicate with each other up to the gas diffusion space 433. Therefore, the through-holes (the gas flow paths 411, 421, and 431 and the through-flow paths 412, 422, and 432) used for supplying the gas can also be used as holes for inserting the electrode rods therethrough when the alumite process is performed and exhausting the solution after the alumite process. For example, in the example illustrated in FIG. 7, the through-flow paths 412, 422, and 432 can be used as through-holes for inserting the electrode rods, and the liquid drain holes 415, 425, and 435 can be used as through-holes for exhausting the solution from the gas diffusion spaces 413, 423, and 433. Accordingly, the number of alumite film formation through-holes can be reduced. As a result, a freedom degree of design of the coolant passage 500 may be improved.

Further, different materials can be used, such as the gas uniform distribution layer 212 (the first plate 210) being formed of stainless steel, the flow path forming layer 222 (the second plate 220) being formed of aluminum, and the like. Meanwhile, any of the gas uniform distribution layer 212 (the first plate 210) and the flow path forming layer 222 (the second plate 220) may be formed of aluminum.

In addition, in the cooling plate 131 according to the present embodiment, the coolant passage 502 is disposed below the gas uniform distribution layer 212. Therefore, the coolant passage 502 can be brought closer to the shower plate 132, as compared with the cooling plate 131A according to the reference example. Accordingly, cooling efficiency can be improved. Further, by reducing the number of alumite film formation through-holes, an area in which the coolant passage 502 is formed can be widened, and the cooling efficiency can be improved. As a result, since it is possible to improve a heat exhaust property with respect to the heat input from the plasma, it is also possible to handle a process of outputting a higher-power RF signal from the RF power source 31.

The substrate processing apparatus 1 provided with the cooling plate 131 according to the present embodiment is described as a plasma processing apparatus that generates a plasma in the plasma processing chamber 10. Meanwhile, the present embodiment is not limited thereto. The cooling plate 131 may be applied to, for example, a substrate processing apparatus such as a thermal chemical vapor deposition (CVD) apparatus.

Although embodiments and the like of a plasma processing system are described above, the present disclosure is not limited to the above-described embodiments and the like, and various modifications and improvements are possible within the scope of the present disclosure described in the claims.

1. A substrate processing apparatus comprising:
a processing chamber;
a substrate support that is disposed in the processing chamber and holds a substrate; and
a shower head facing the substrate support,
the shower head including:
a shower plate formed with a gas flow path through which a gas is discharged; and
a cooling plate holding and cooling the shower plate, and
the cooling plate including:
a first plate having a gas distribution layer through which the gas is distributed;
a second plate having a coolant passage through which a coolant is supplied and a gas diffusion space into which the gas distributed by the gas distribution layer is supplied; and
a fastening member fastening the first plate and the second plate.

2. The substrate processing apparatus according to claim 1,
wherein the first plate includes:
a connection interface layer to which the gas is supplied from a gas supply;
the gas distribution layer through which the gas supplied from the connection interface layer is distributed; and
a first intermediate interface layer through which the gas distributed by the gas distribution layer is supplied to the second plate.

3. The substrate processing apparatus according to claim 1,
wherein the second plate includes:
a second intermediate interface layer to which the gas is supplied from the first plate;
a flow path forming layer having the coolant passage and the gas diffusion space into which the gas is supplied from the second intermediate interface layer; and
a gas hole layer through which the gas is supplied from the gas diffusion space to the shower plate.

4. The substrate processing apparatus according to claim 1,
wherein the coolant passage is disposed below the gas distribution layer.

5. The substrate processing apparatus according to claim 1,
wherein the gas distribution layer has a multilayer structure in which an upper surface gas flow path formed on an upper surface side, a lower surface gas flow path formed on a lower surface side, and a through-flow path passing through the upper surface side and the lower surface side are formed.

6. The substrate processing apparatus according to claim 1,
wherein a sealing member is provided on a facing surface of the first plate and the second plate.

7. The substrate processing apparatus according to claim 1,
wherein the first plate and the second plate are formed of aluminum.

8. The substrate processing apparatus according to claim 1,
wherein the first plate is formed of stainless steel, and
the second plate is formed of aluminum.

9. The substrate processing apparatus according to claim 1,
wherein the second plate is disposed closer to a plasma processing space side than the first plate.
